(19) United States
(12) Patent Application Publication
(10) Pub. No.: US 2013/0174899 A1
(43) Pub. Date: Jul. 11, 2013

(54) A-SI:H ABSORBER LAYER FOR A-SI SINGLE- AND MULTIJUNCTION THIN FILM SILICON SOLAR CELLS

(71) Applicant: Marian Fecioru-Morariu, Chur (CH)

(72) Inventor: Marian Fecioru-Morariu, Chur (CH)

(73) Assignee: TEL SOLAR AG, Trubbach (CH)

(21) Appl. No.: 13/820,218

(22) PCT Filed: Sep. 2, 2011
(86) PCT No.: PCT/EP2011/065202

§ 371 Date: Mar. 1, 2013

Related U.S. Application Data
(60) Provisional application No. 61/379,861, filed on Sep. 3, 2010.

(51) Int. Cl. H01L 31/0687; H01L 31/0376; H01L 31/18

(52) U.S. Cl. CPC H01L 31/06875; H01L 31/1804; H01L 31/03762
USPC 136/255; 438/96; 136/258

(57) ABSTRACT

In order to improve a thin film solar cell with an amorphous silicon absorber layer being in single or in tandem configuration, the addressed absorber layer of a-Si:H is manufactured by plasma enhanced vapor deposition in an RF-SiH₄ plasma, wherein the deposition is performed at at least one of at the process pressure below 0.5 mbar and of at an RF power density below 370 W/14000 cm₂.

The present invention relates to a novel method for improving the performance of amorphous Silicon (a-Si) single junction solar cells as well as of micromorph tandem solar cells by increasing the initial efficiency and simultaneously reducing the light induced degradation of the a-Si and micromorph tandem cells in large area mass production PV systems.

### FIELD OF THE INVENTION

Photovoltaic devices or solar cells are devices which convert light into electrical power. The thin film solar cells are of a particular importance for low-cost mass production since they allow for using inexpensive substrates (e.g. glass) and thin films of Si with the thickness in the range of 100 nm-2 μm. One of the most used methods for the deposition of such Si layers is the PECVD method.

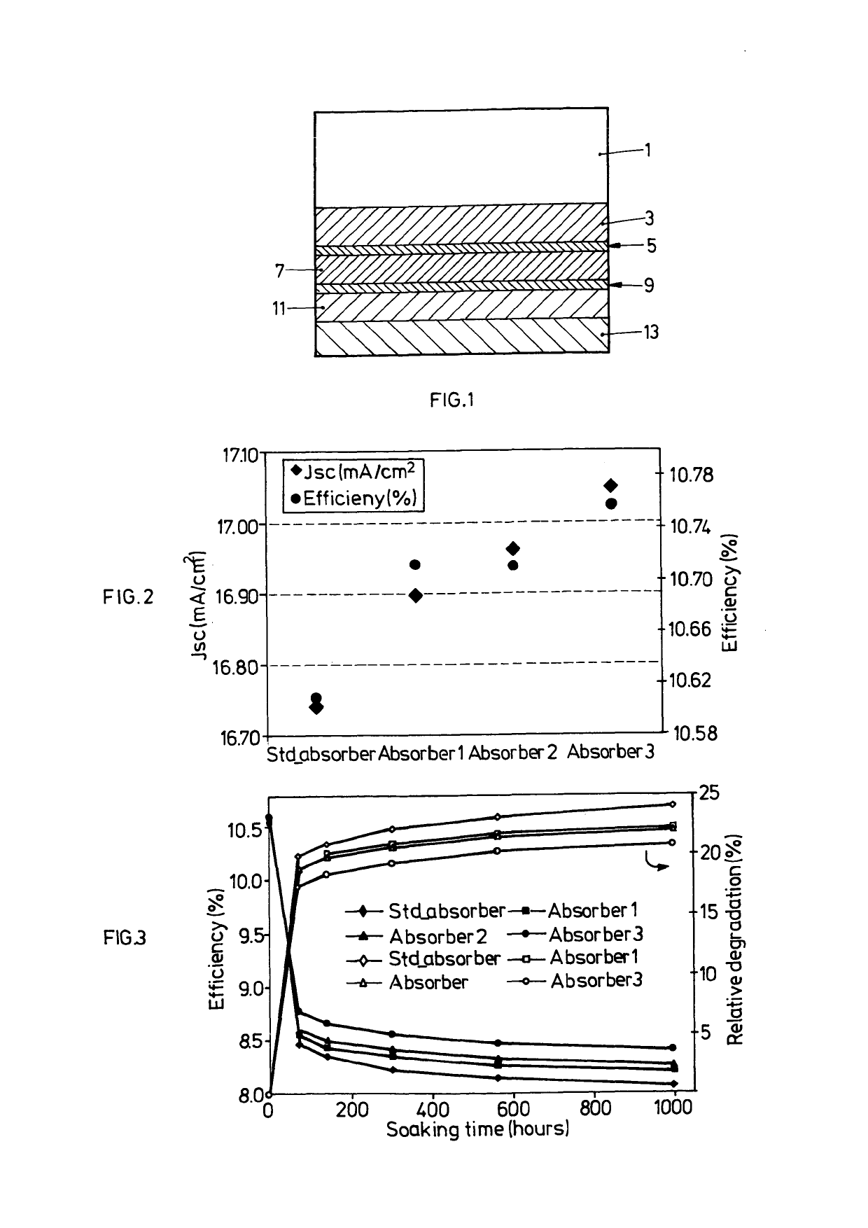

A known simple thin film solar cell in the so-called superstrate configuration is shown in FIG. 1. It generally includes a transparent glass-substrate 1 and a transparent conductive oxide layer 3 deposited on glass, i.e. the front contact (or electrode) (TCO-FC) of the solar cell. The Si layers are deposited on the TCO front contact layer 3: first a positively doped Si layer, i.e. the p-layer 5, then the intrinsic absorber layer (i-layer) 7 and the negatively doped n-layer 9. The three Si layers 5,7,9 create a p-i-n junction. The main part of the thickness of the Si layers is occupied by i-layer 7 and the photoelectric conversion occurs primarily in this i-layer 7. On top of the Si layers 5,7,9 another TCO layer (TCO-BC) 11 is deposited which is also named back-contact. The TCO front and back contact layers 3,11 could be made of zinc oxide, tin oxide or ITO. A white reflector 13 is usually applied after the back contact layer 11.

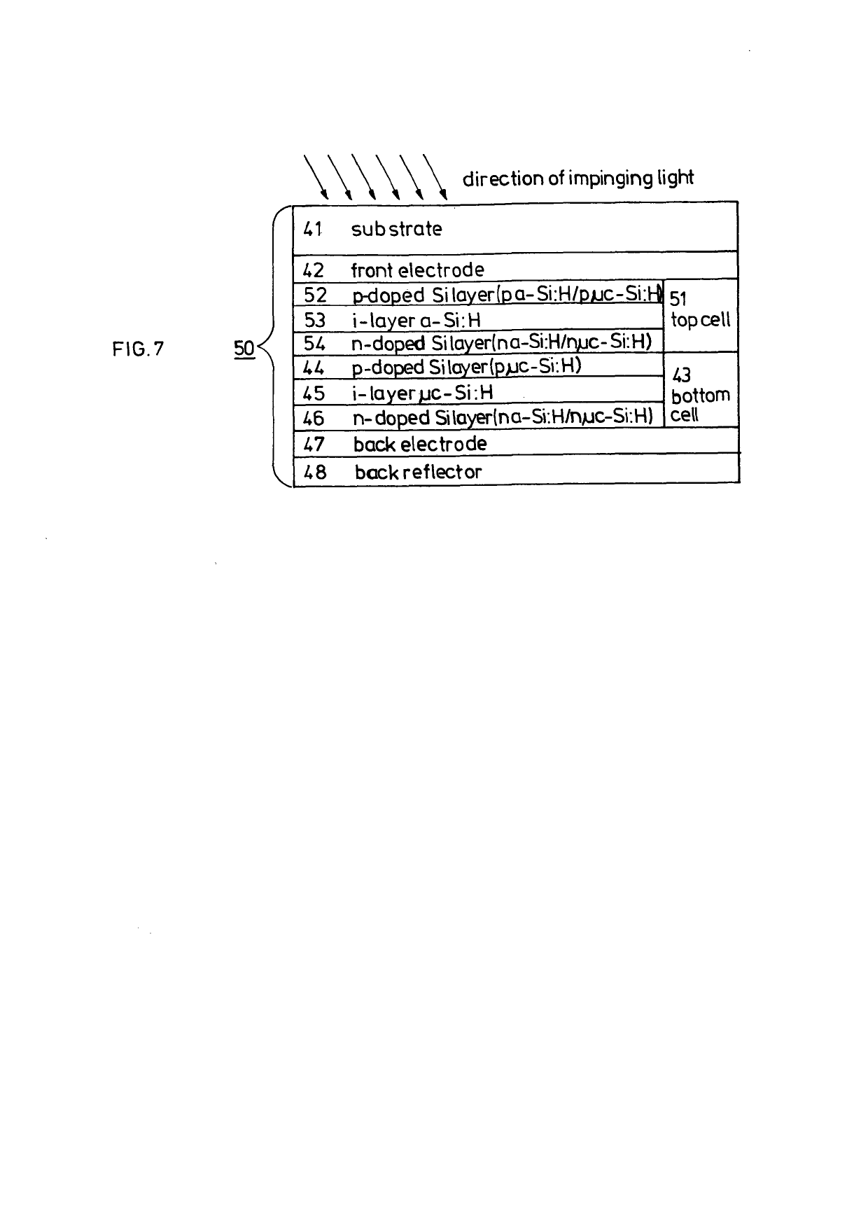

In the past years a new concept of tandem cells has been developed. The tandem cell allow for a better use of the solar spectra and for a reduced light induced degradation. It is based on two single junction cells deposited one on top of the other one. In the case of micromorph tandem cells the top cell is an a-Si cell and the bottom cell is a microcrystalline (mc-Si) silicon cell, see FIG. 7.

Thereby FIG. 7 shows a prior Art-tandem junction thin film silicon photovoltaic cell. The thicknesses are not to scale.

The a-Si cell absorbs preponderantly the blue part of the solar spectrum while the micro-crystalline cell absorbs mostly the red part of the solar spectra. The serial connection of the two junctions also helps to reduce the light induced degradation which is specific for the a-Si cells.

### DEFINITIONS

“Processing” in the sense of this invention includes any chemical, physical or mechanical effect acting on substrates.

“Substrates” in the sense of this invention are components, parts or workpieces to be treated in an inventive processing apparatus. Substrates include but are not limited to flat, plate shaped parts having rectangular, square or circular shape. In a preferred embodiment this invention addresses essentially planar substrates of a size >1 m², such as thin glass plates.

A “vacuum processing” or “vacuum treatment system or apparatus” comprises at least an enclosure for substrates to be treated under pressures lower than ambient atmospheric pressure.

“CVD” Chemical Vapour Deposition is a well known technology allowing the deposition of layers on heated substrates. A usually liquid or gaseous precursor material is being fed to a process system where a thermal reaction of said precursor results in deposition of said layer. “LPCVD” is a common term for low pressure CVD.

“DEZ”—diethyl zinc is a precursor material for the production of TCO layers in vacuum processing equipment.

“TCO” stands for transparent conductive oxide, “TCO layers” consequently are transparent conductive layers.

The terms “layer”, “coating”, “deposit” and “film” are interchangeably used in this disclosure for a film deposited in vacuum processing equipment, be it CVD, LPCVD, plasma enhanced CVD (PECVD) or PVD (physical vapour deposition)

A “solar cell” or “photovoltaic cell” (PV cell) is an electrical component, capable of transforming light (essentially sun light) directly into electrical energy by means of the photoelectric effect.

A “thin-film solar cell” in a generic sense includes, on a supporting substrate, a p-i-n junction established by a thin film deposition of semiconductor compounds, sandwiched between two electrodes or electrode layers. A p-i-n junction or thin-film photoelectric conversion unit includes an intrinsic semiconductor compound layer sandwiched between a p-doped and an n-doped semiconductor compound layer. The term “thin-film” indicates that the layers mentioned are being deposited as thin layers or films by processes like, PEVCD, CVD, PVD or alike. Thin layers essentially mean layers with a thickness of 10 μm or less, especially less than 2 μm.

### BACKGROUND OF THE INVENTION

FIG. 7 shows a tandem-junction silicon thin film solar cell as known in the art. Such a thin-film solar cell 50 usually includes a first or front electrode 42, one or more semiconductor thin-film p-i-n junctions (52-54, 51, 44-46, 43), and a second or back electrode 47, which are successively stacked on a substrate 41. Each p-i-n junction 51, 43 or thin-film photoelectric conversion unit includes an i-type layer 53, 45 sandwiched between a p-type layer 52, 44 and an n-type layer 54, 46 (p-type=positively doped, n-type=negatively doped). Substantially intrinsic in this context is understood as undoped or exhibiting essentially no resultant doping. Photoelectric conversion occurs primarily in this i-type layer; it is therefore also called “absorber” layer.

Depending on the crystalline fraction (crystallinity) of the i-type layer 53, 45 solar cells or photoelectric (conversion) devices are characterized as amorphous (a-Si, 53) or microcrystalline (μc-Si, 45) solar cells, independent of the kind of crystallinity of the adjacent p and n-layers. “Microcrystalline” layers are being understood, as common in the art, as layers comprising of a significant fraction of crystalline silicon—so called micro-crystallites—in an amorphous matrix. Stacks of p-i-n junctions are called tandem or triple junction photovoltaic cells. The combination of an amorphous and microcrystalline p-i-n-junction, as shown in FIG. 7, is also called “micromorph” tandem cell.

### Drawbacks Known in the Art

In order to achieve a high stabilized efficiency of single junction a-Si solar cells as well as of tandem solar cells one needs to optimize the most important cell parameters that account for the cell efficiency: current density Jsc, open circuit voltage Voc, and the fill factor FF. Additionally, the light induced degradation (LID) should be reduced as much as possible. For large area mass production solar cells additional factors such as layer and cell uniformity or deposition time are also very important factors that have to be considered.

Usually, good stabilized efficiency values could be obtained through a complex optimization process of either the initial efficiency (by improving one or more cell parameters) or of the LID. Such an optimization process usually comprises a trade off between initial efficiency, stabilized efficiency and deposition rate.

### DESCRIPTION OF THE INVENTION

It is an object of the present invention to improve a thin film a-Si solar cell, be it in single or tandem or even higher order stapled configuration.

This is achieved by the method of manufacturing an absorber layer of a-Si:H of a thin film solar cell by plasma-enhanced-vapor-deposition, PECVD, in a RF-SiH₄ plasma, comprising at least one of the steps of
a) performing said deposition at a process pressure below 0.5 mbar and of
b) performing said deposition at a RF-power density below 370 W/14 000 cm².

The present invention thereby addresses a method for increasing the initial efficiency (by increasing the current density) and simultaneously reducing the LID of a-Si single junction cells. This is done by improving generically the material quality and adjusting the properties of the absorber layer of the a-Si cell. By applying this method a higher stabilized efficiency for a-Si single junction cells as well as for tandem cell is achieved. Moreover, for micromorph tandem cells the combination of reduced top cell degradation and higher top cell current leads to significantly lower LID and to significantly higher stabilized module power.

In one variant the method according to the invention comprises both steps a) and b).

In one variant of the method according to the invention the process pressure value is selected to be at least 0.3 mbar.

In one variant of the method according to the invention only step a) is performed at a pressure value of 0.45 mbar.

In one variant of the method according to the invention only step b) is performed at a power density value of 270 W/14000 cm².

In one variant of the method according to the invention wherein steps a) and b) are performed, the process pressure is selected to 0.4 mbar and the power density to 230 W/14000 cm².

The invention further addresses a photovoltaic absorber layer of a-Si:H comprising at least one of:
i. a microstructure factor R (%) less than 10.5
ii. a H content c_{H} (at. %) below 13.7.

Thereby this absorber layer, in one embodiment, is manufactured according to one of the variants of the method according to the invention, thereby especially in which both steps a) and b) are performed and the pressure value is thereby selected to be at most 0.3 mbar or wherein the process pressure is 0.4 mbar and the power density 230 W/14000 cm².

The invention further addresses a single junction a-Si solar cell comprising a low-pressure-chemical-vapor deposited (LPCVD) ZnO front contact layer the absorber layer comprising at least one of:
i. an microstructure factor R (%) less than 10.5
ii. a H content c_{H} (at. %) below 13.7,
   in one of the embodiments as addressed above.

In the single junction a-Si solar cell according to the invention and in one of its embodiments the absorber layer has a thickness of 265 nm.

In the single junction a-Si solar cell according to the invention and in one of its embodiments there is valid, at least one of:
I. the current density J_{sc} is higher than 16.8 mA/cm²
II. the efficiency is higher than 10.62%.

In one embodiment of the single junction a-Si solar cell according to the invention features I and II are valid.

In one embodiment the single junction a-Si cell has an absolute stabilized efficiency after 1000 h light soaking of at least 8.25% and a relative light induced degradation of less than 22%.

The invention further addresses a micromorph solar tandem cell comprising a top and a bottom cell, wherein the top cell comprises an a-Si absorber layer comprising both of:
i. an microstructure factor R (%) less than 10.5
ii. a H content c_{H} (at. %) below 13.7
   preferably manufactured by the variant of the method according to the invention in which both steps a) and b) are performed with its further variants as addressed above. Preferably the micromorph solar tandem cell is manufactured by the method according to the invention in the variant, wherein both steps a) and b) are performed, and the variants thereto.

### DETAILED DESCRIPTION OF THE INVENTION

The invention shall further be exemplified with the help of figures.

These figures show:

FIG. 2: The current density and cell efficiency for a-Si single junction solar cells comprising different absorber layers;

FIG. 3: The loss of cell efficiency as a function of light soaking time for a-Si single junction cells with different absorber layers whereby the relative degradation of the cells is also shown for comparison. The filled symbols refer to the absolute efficiency while the empty symbols refer to the relative light induced degradation. The thickness of the absorber layer is 265 nm for all cells;

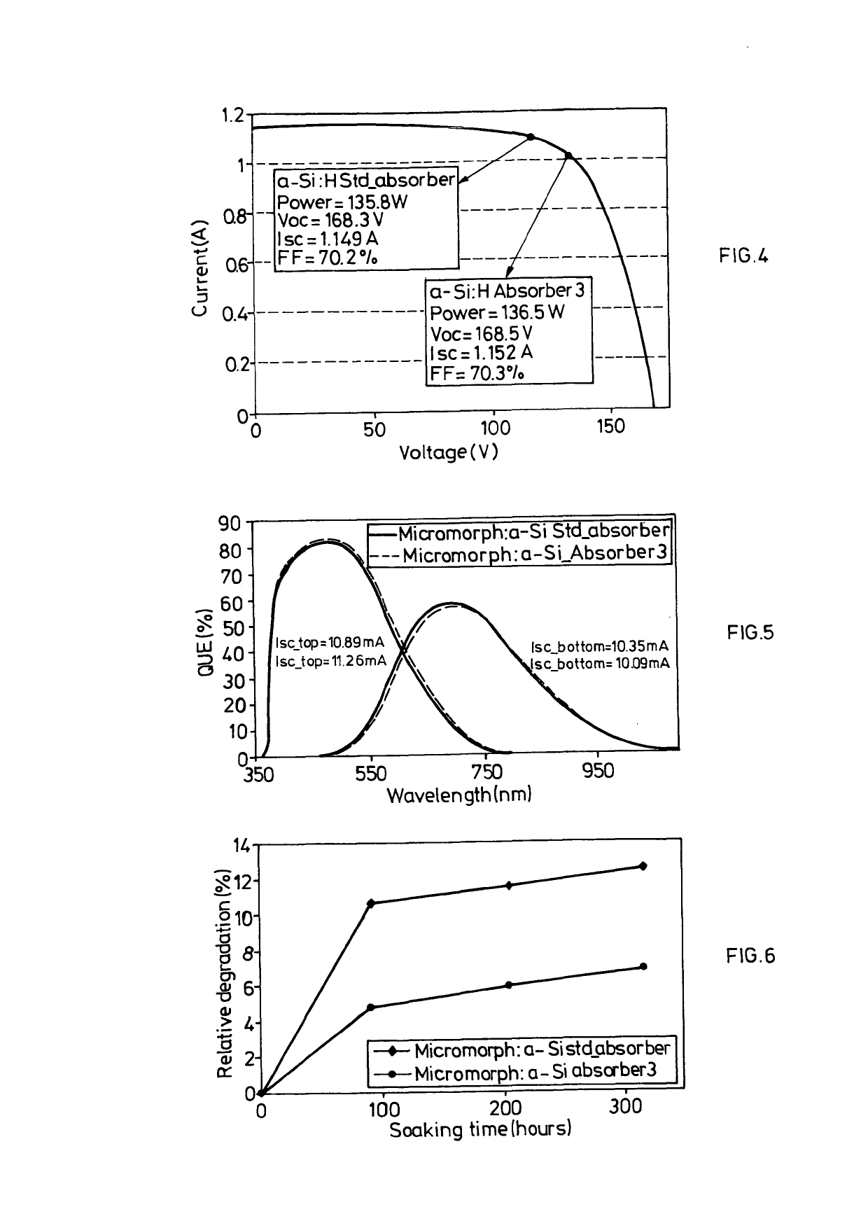

FIG. 4: The current/voltage curves of two micromorph modules for which the top cell comprises the standard a-Si:H absorber layer and the a-Si:H absorber3 layer, respectively.

FIG. 5: The quantum efficiency curves in reverse bias corresponding to the micromorph modules shown in the FIG. 4. The currents for the top and bottom cells are also given in the Figure.

FIG. 6: The relative degradation of mini-modules corresponding to the micromorph modules shown in the FIG. 4.

Please note, that throughout the figures “Std” stands for “prior art”.

Within the present invention, the PECVD process for the deposition of hydrogenated amorphous Si (a-Si:H) absorber layers is tuned in order to obtain a better material quality and higher current density. The common method of increasing the current density of an a-Si cell is to reduce the band gap energy of the absorber layer by reducing the H-dilution of the SiH₄ plasma. However, at least two negative effects can arise when applying this method: the Voc decreases and the LID increases. Contrary to the common method, a combination of reduced process pressure and RF power density is employed here in order to simultaneously increase the current density and reduce the light induced degradation. The deposition rate is the trade off factor of this method.

### Single Layers

A state of the art a-Si:H absorber layer for large area mass production a-Si and tandem solar cells is deposited by diluting the SiH₄ gas by H₂ in a ratio of 1:1. Typical deposition rates for such absorber layers are about 3.2-3.6 Å/sec.

By reducing according to the present invention either the process pressure (down to 0.3 mbar) or the RF power density one can improve the material quality and slightly reduce the band gap energy of the a-Si:H absorber layer. This is shown in the Table 1 where process parameters and single layer properties of the a-Si:H layers as discussed are presented also for two absorber layers for which either the process pressure (absorber1) or the RF power density (absorber2) was reduced. The material quality factor (or microstructure factor-R, derived from FTIR measurements), which is a measure of the micro-voids in the material is reduced for the absorber1 and absorber2, denoting a dense material with less Si—H₂ and Si—H₃ bonds. The improved material quality and the reduced H-content incorporated in the absorber1 and absorber2 layers with respect to the standard a-Si:H absorber layer are two factors which are thought to contribute to a lower light induced degradation. The deposition rate of the absorber1 and absorber2 layers is slightly reduced. The layer non-uniformity over large area (1.4 m²) of the absorber2 layer is slightly higher than that of the standard absorber layer.

Significant improvement of material quality and reduction of band gap energy is given by the combination of reduced process pressure and RF power in the a-Si:H PECVD process. This is also shown in the Table 1 for the absorber3 layer. The material parameters of the absorber3 layer are significantly improved with respect to those of the standard absorber and the absorber1 and absorber2: much better microstructure factor, i.e. significantly less micro-voids and denser material as well as significantly lower H-content incorporated in the layer. The band gap energy E₀₄ is also slightly reduced for the absorber3 layer. The deposition rate of the absorber3 layer is lower, but still above 2 Å/sec. Such a-Si:H absorber layers with excellent material quality at lower deposition rate are very interesting for large area mass production a-Si single junction and a-Si based tandem solar cells for which a lower light induced degradation and higher stabilized power are required.

TABEL 1

| | Standard | Absorber | Absorber | Absorber |
|---|---|---|---|---|
| | Absorber | 1 | 2 | 3 |
| (H₂/SiH₄) flow | 1 | 1 | 1 | 1.5 to 1 |
| ratio | | | | |
| Process pressure | 0.5 | 0.45 | 0.5 | 0.4 |
| (mbar) | | | | |
| RF power (W) | 370 | 370 | 270 | 230 |
| Thickness non- | 14.2 | 14.0 | 16.8 | 13.0 |
| uniformity (%) | | | | |
| Deposition Rate | 3.6 | 3.2 | 2.7 | 2.1 |
| (Å/sec) | | | | |
| Band gap energy | 1.830 | 1.826 | 1.821 | 1.815 |
| E₀₄ (eV) | | | | |
| H-content c_{H} | 13.7 | 12.8 | 12.0 | 10.1 |
| (at. %) in material | | | | |
| Microstructure | 10.5 | 7.5 | 7.8 | 3.9 |
| factor R (%) | | | | |

a-Si Single Junction Results

Single junction a-Si solar cells with the above described absorber layers have been prepared on LPCVD ZnO FC. For all cells the thickness of the absorber layer was 265 nm and beside the different absorber layers the cell structure was the same for all cells.

The current density Jsc and the cell efficiency of the cells with different absorber layers are shown in FIG. 2. The current density of the cells comprising the new absorber layers is higher than that of the cells comprising the standard a-Si:H absorber layer. The most significant increase in current density corresponds to the absorber3 layer for which the combination of reduced process pressure and RF power density was applied. The higher current density of the solar cells including the new absorber layers is due to a slightly lower band gap energy and improved material quality, as shown in the Table 1.

Since the open circuit voltage and the fill factor of the above mentioned cells do not change significantly for the different absorber layers, the cell efficiency is mainly driven by the current density. FIG. 2 also shows that the cell efficiency follows a similar trend as that of the current density: the lowest cell efficiency corresponds to the standard a-Si:H absorber layer while the highest one to the absorber3 layer. The values of current density and cell efficiency shown in the FIG. 2 are average values of 16 test cells distributed over a 1.4 m² a-Si solar module.

FIG. 3 shows the decrease of efficiency of the solar cells comprising the different absorber layers due to light induced degradation. After 1000 hours of light soaking the efficiency of the cells that include the standard a-Si:H absorber layer is slightly above 8%. The cells comprising the absorber1 and absorber2 layers have similar stabilized efficiency values of about 8.25%. This gain in efficiency obtained for the absorber1 and absorber2 layers corresponds to a stabilized power gain of about 2.5 W for a 1.4 m² solar a-Si module. The highest stabilized efficiency of 8.41% after 1000 hours light soaking is obtained for the cells containing the absorber3 layer. The net gain in stabilized efficiency due to the absorber3 layer is about 0.34% abs. which corresponds to a stabilized power gain of about 4.5 W for a 1.4 m² a-Si solar module.

FIG. 3 also shows the relative degradation of the solar cells comprising the different absorber layers (all 265 nm thick). The cells comprising the standard a-Si:H absorber layer not only have the lowest stabilized efficiency but they also show the largest relative degradation with respect to the cells comprising the new a-Si:H absorber layers. The cells that include the absorber1 and absorber2 layers have similar relative degradation values slightly above 22%. After 1000 hours light soaking the lowest relative degradation of 20.8% corresponds to the absorber3 layer.

The initial and stabilized performance of the solar cells with the different absorber layers strongly correlate with the single layer properties of the different absorber layers shown in the Table 1. For instance, the highest current density, highest stabilized efficiency and lowest relative degradation for the absorber3 layer are the consequence of the best material quality of this absorber layer with respect to the other absorber layers.

### Micromorph Tandem Results

The new a-Si:H absorber layers were primarily optimized for being used in top cells of micromorph tandem cells. However, they might be used in any single, double or triple junction cell concept when more current density and lower light induced degradation are needed.

FIG. 4 shows the current-voltage curves of two 1.4 m² micromorph tandem modules. The two modules differ only in the absorber layer of the top cell: one module comprises a standard a-Si:H absorber layer while the other one includes the absorber3 layer. The thicknesses of the absorber layers of the two modules were: 200 nm a-Si:H absorber layer for top cell, 1000 nm microcrystalline Si (pc-Si:H) absorber layer for bottom cell. All parameters of the current-voltage characteristics of the module comprising the absorber3 in the top cell are slightly improved over those of the module that include the standard a-Si:H absorber resulting in a slightly higher initial power for the module with the a-Si:H absorber3 layer.

The external quantum efficiency curves in reversed bias corresponding to the two modules are shown in the FIG. 5. The currents of the top and bottom cells corresponding to the two modules are also given in the FIG. 5. The top cell comprising the absorber3 layer has a higher current with respect to the top cell including the standard a-Si:H absorber layer. According to the quantum efficiency data, this gain in current is due to a stronger light absorption of the absorber3 layer over the entire wavelength range where the top cell does absorb. The lower band gap energy of the absorber3 layer with respect to the standard a-Si:H absorber layer is evidenced by the stronger quantum efficiency gain in the wavelength range between 750-500 nm. Accordingly, the quantum efficiency and therefore the current of the bottom cell are reduced due to the stronger absorption in the top cell that includes the absorber3 layer.

This leads to a larger difference between the top and bottom cell currents. Hence, the bottom cell current limitation in the module comprising the absorber3 layer is significantly stronger than that corresponding to the module with the standard a-Si:H absorber layer.

The top-bottom cell current limitation could be preserved when using the absorber3 in the top cell by e.g. increasing the thickness of the bottom cell absorber layer so that the bottom cell current is proportionally increased with the top cell current. For the case of bottom limited tandem modules this will result in a significantly increase in the module power in the initial state while the light induced degradation is expected to be also lower due to the lower degradation of the absorber3 layer.

FIG. 6 shows the relative degradation of micromorph mini-modules for which the top cell includes the standard a-Si:H absorber layer and the absorber3 layer, respectively. The thicknesses of top and bottom cells as well as the cell structure are the same as for the 1.4 m² micromorph modules (discussed above). As shown in the FIG. 6, the light induced degradation is significantly lower for the micromorph modules comprising the a-Si:H absorber3 layer than for the modules that include the standard a-Si:H absorber layer. After more than 300 hours of light soaking the relative degradation of the micromorph module with the standard a-Si:H absorber layer is above 12% while the module comprising the a-Si:H absorber3 layer degrades less than 7%. This major difference in the relative degradation of the mini-modules comprising the two different absorber layers is mainly due to (i) lower relative degradation of the a-Si:H absorber3 layer with respect to the standard a-Si:H absorber (as shown in the FIG. 2) and (ii) due to the higher current of the top cell that includes the absorber3 as compared to that of the top cell with the standard a-Si:H absorber layer. As shown by the quantum efficiency data (FIG. 5) in the case of the micromorph module with the a-Si:H absorber3 layer, this higher top cell current leads to a significantly stronger bottom cell current limitation which additionally contributes to a lower relative degradation.

This major difference in the relative degradation of the two micromorph modules leads to a significant difference in the stabilized power of the two modules. The stabilized power of the two micromorph modules is about 119 W for the micromorph module comprising the standard a-Si:H absorber layer and slightly above 127 W for the micromorph module comprising the a-Si:H absorber3 layer. Hence, a significantly higher stabilized power of micromorph modules is achieved when using the slower and better material quality a-Si:H absorber3 layer.

1) A method of manufacturing an absorber layer of a-Si:H of a thin film solar cell by plasma-enhanced-vapor deposition PECVD in a RF-SiH₄ plasma, comprising at least one of the steps of
a) performing said deposition at a process pressure below 0.5 mbar
b) performing said deposition at a RF power density below 370 W/14 000 cm².

2) The method of claim 1 comprising steps a) and b).

3) The method of one of claim 1 or 2 comprising selecting said process pressure value to be at least 0.3 mbar.

4) The method of claim 1 comprising performing only step a) at a pressure value of 0.45 mbar.

5) The method of claim 1 comprising performing only step b) at a power density value of 270 W/14000 cm².

6) The method of claim 2 thereby selecting said process pressure to 0.4 mbar and said power density to 230 W/14000 cm².

7) A photovoltaic absorber layer of a-Si:H comprising at least one of:
i. an microstructure factor R (%) less than 10.5
ii. a H content c_{H} (at. %) below 13.7.

8) The absorber layer of claim 7 manufactured according to the method of one of claims 1 to 6.

9) The absorber layer of claim 7 or 8 manufactured according to one of claims 2, 3, 6.

10) A single junction a-Si solar cell, comprising a low-pressure-chemical-vapor deposited (LPCVD) ZnO front contact layer comprising an absorber layer according to one of claims 7 to 9.

11) The a-Si solar cell according to claim 10 wherein the absorber layer has a thickness of 265 nm.

12) The a-Si solar cell of one of claim 10 or 11 wherein there is valid, at least one of:
I. The current density J_{sc} is higher than 16.8 ma/cm²
II. The efficiency is higher than 10.62%.

13) The a-Si solar cell of claim 12 wherein I. and II. are valid.

14) The a-Si solar cell of one of claims 10 to 12 having an absolute stabilized efficiency after 1000 h light soaking of at least 8.25% and a relative light induced degradation of less than 22%.

15) A micromorph solar tandem cell comprising a top and a bottom cell, wherein the top cell comprises an a-Si absorber layer according to claim 7 wherein i. and ii. are fulfilled, preferably manufactured according to claim 9.
